(19) United States
(12) Patent Application Publication
(10) Pub. No.: US 2005/0277302 A1
(43) Pub. Date: Dec. 15, 2005

(54) Advanced low dielectric constant barrier layers

(76) Inventors: Son Van Nguyen, Los Gatos, CA (US); Hichem M'Saad, Santa Clara, CA (US); Bok Hoen Kim, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/139,436

(22) Filed: May 27, 2005

Related U.S. Application Data
(60) Provisional application No. 60/575,663, filed on May 28, 2004.

(51) Int. Cl. H01L 21/469

(52) U.S. Cl. 438/763; 438/786; 438/778

(57) ABSTRACT

Methods are provided for depositing a doped barrier layer material having a low dielectric constant. In one aspect, the invention provides a method for processing a substrate including depositing a barrier layer on the substrate by introducing a processing gas comprising an organosilicon compound, at least one dopant containing gas, hydrogen gas, and, optionally, an inert gas into a processing chamber, reacting the processing gas to deposit the barrier layer, and depositing a first dielectric layer adjacent the barrier layer. The organosilicon compound may comprise a phenylsilane containing compound or an aliphatic organosilicon compound. The processing gas may further comprise an oxygen containing compound, a nitrogen containing compound, or both.

### CROSS-REFERENCE TO RELATED APPLICATIONS

This application claims benefit of U.S. Provisional Patent Application Ser. No. 60/575,663, filed May 28, 2004, which is herein incorporated by reference.

### BACKGROUND OF THE DISCLOSURE

1. Field of the Invention

The invention relates to the fabrication of integrated circuits, more specifically to a process for depositing dielectric layers on a substrate, and to the structures formed by the dielectric layer.

2. Description of the Related Art

Semiconductor device geometries have dramatically decreased in size since such devices were first introduced several decades ago. Since then, integrated circuits have generally followed the two year/half-size rule (often called Moore's Law), which means that the number of devices that will fit on a chip doubles every two years. Today's fabrication plants are routinely producing devices having 0.35 μm and even 0.18 μm feature sizes, and tomorrow's plants soon will be producing devices having even smaller geometries.

To further reduce the size of devices on integrated circuits, it has become necessary to use conductive materials having low resistivity and to use insulators having low dielectric constants (dielectric constants of less than 4.0) to also reduce the capacitive coupling between adjacent metal lines. One such low k material is silicon oxycarbide deposited by a chemical vapor deposition process and silicon carbide, both of which may be used as dielectric materials in fabricating damascene features.

One conductive material having a low resistivity is copper and its alloys, which have become the materials of choice for sub-quarter-micron interconnect technology because copper has a lower resistivity than aluminum, (1.7 μΩ-cm for copper compared to 3.1 μΩ-cm for aluminum), a higher current, and higher carrying capacity. These characteristics are important for supporting the higher current densities experienced at high levels of integration and increased device speed. Further, copper has a good thermal conductivity and is available in a highly pure state.

One difficulty in using copper in semiconductor devices is that copper is difficult to etch and achieve a precise pattern. Etching with copper using traditional deposition/etch processes for forming vertical and horizontal interconnects has been less than satisfactory. Therefore, new methods of manufacturing vertical and horizontal interconnects having copper containing materials and low k dielectric materials are being developed.

One method for forming vertical and horizontal interconnects is by a damascene or dual damascene method. In the damascene method, one or more dielectric materials, such as the low k dielectric materials, are deposited and pattern etched to form the vertical interconnects, e.g., vias, and horizontal interconnects, e.g., lines. Conductive materials, such as copper containing materials, and other materials, such as barrier layer materials used to prevent diffusion of copper containing materials into the surrounding low k dielectric, are then inlaid into the etched pattern. Any excess copper containing materials and excess barrier layer material external to the etched pattern, such as on the field of the substrate, are then removed.

However, low k dielectric materials are often porous and susceptible to interlayer diffusion of conductive materials, such as copper, and moisture, both of which can result in the formation of short-circuits and device failure. A dielectric barrier layer material is used in damascene structures to reduce or to prevent interlayer diffusion. However, traditional dielectric barrier layer materials, such as silicon nitride, often have high dielectric constants of 7 or greater. The combination of such a high k dielectric material with surrounding low k dielectric materials results in dielectric stacks having a higher than desired dielectric constant.

Therefore, there remains a need for dielectric barrier layer materials with low dielectric constants for damascene applications.

### SUMMARY OF THE INVENTION

Aspects of the invention generally provide a method for depositing a phosphorus doped barrier layer material having a low dielectric constant. In one aspect, the invention provides a method for processing a substrate including depositing a barrier layer on the substrate by introducing into a processing chamber a processing gas comprising an oxygen-free organosilicon compound, a phosphorus containing gas, and hydrogen, wherein the oxygen-free organosilicon compound has the formula SiHₐ(CH₃)_{b}(C₆H₅)_{c}, and a is 0 to 3, b is 0 to 3, and c is 1 to 4 and reacting the processing gas to deposit the barrier layer, wherein the barrier layer has a dielectric constant less than 5 and depositing a dielectric layer adjacent the barrier layer, wherein the dielectric layer comprises silicon, oxygen, and carbon and has a dielectric constant of about 3 or less.

In another aspect, a method is provided for processing a substrate including depositing a barrier layer by a method including introducing to the processing chamber a processing gas comprising a compound comprising oxygen and carbon, an oxygen-free organosilicon compound, a phosphorus containing gas, and an inert gas and reacting the processing gas to deposit a barrier layer on the substrate, wherein the barrier layer comprises silicon, oxygen, and carbon and has an oxygen content of about 15 atomic percent or less and a dielectric constant of about 4 or less and depositing a dielectric layer adjacent the barrier layer, wherein the dielectric layer comprises silicon, oxygen, and carbon and has a dielectric constant of about 3 or less.

### BRIEF DESCRIPTION OF THE DRAWINGS

So that the manner in which the above aspects of the invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a cross sectional view showing a dual damascene structure comprising a low k barrier layer and a low k dielectric layer described herein; and

FIGS. 2A-2H are cross sectional views showing one embodiment of a dual damascene deposition sequence of the invention.

For a further understanding of aspect of the invention, reference should be made to the ensuing detailed description.

### DETAILED DESCRIPTION OF THE PREFERRED EMBODIMENTS

The words and phrases used herein should be given their ordinary and customary meaning to one skilled in the art unless otherwise further defined. The following deposition processes are described as though used in the 300 mm Producer™ dual deposition station processing chamber (Commercially available from Applied Materials, Inc., of Santa Clara, Calif.), and should be interpreted accordingly; for example, flow rates are total flow rates and should be divided by two to describe the process flow rates at each deposition station in the chamber. Additionally, it should be noted that the respective parameters may be modified to perform the plasma processes in various chambers and for different substrate sizes, such as for 200 mm substrates.

Aspects of the invention described herein refer to methods and compounds for depositing a phosphorus doped silicon carbide (SiCP) barrier layer material having a low dielectric constant, such as a dielectric constant of about 5 or less. It is believed the deposition of phosphorus doping of a silicon carbide based material will have improved moisture resistance and better barrier properties of resistance to metals diffusion, such as copper, and to mobile ions, either metal or non-metal.

The phosphorus doped silicon carbide layer may be deposited by reacting a processing gas of an organosilicon compound and a phosphorus containing gas. The processing gas may further include hydrogen, inert gas, or a combination thereof. The organosilicon compound may comprise phenylsilanes and/or aliphatic organosilicon compounds. The processing gas may further comprise an oxygen containing compound, a nitrogen containing compound, a dopant, or a combination thereof. Depositing a phosphorus doped silicon carbide compound with an oxygen containing compound can be used to form a phosphorus and oxygen doped silicon carbide layer (SiC—OP).

Phosphorus doping of the low k silicon carbide layer may be performed by introducing a phorphorus containing gas, for example, phosphine (PH₃), triethylphosphate (TEPO), triethoxyphosphate (TEOP), trimethyl phosphine (TMP), triethyl phosphine (TEP), and combinations thereof, into the chamber with the organosilicon compound, and any other processing gases. It is believed that dopants may reduce the dielectric constant of the deposited silicon carbide material.

Phosphorus containing dopants may be used in the processing gases at a ratio of dopant to organosilicon compound between about 1:5 or greater, such as between about 1:5 and about 1:100. The phosphorus doped silicon carbide layer generally includes less than about 15 atomic percent (atomic %) or less of phosphorus. The phosphorus doped silicon carbide layer may comprise between about 0.1 wt. % and about 15 wt. % of phosphorus, for example, between about 1 wt. % and about 4 wt. % of phosphorus.

Suitable organosilicon compounds for depositing silicon carbide based materials include oxygen-free organosilicon compounds. Examples of oxygen free organosilicon compounds include phenylsilanes oxygen-free aliphatic organosilicon compounds, oxygen-free cyclic organosilicon compounds, or combinations thereof, having at least one silicon-carbon bond. Examples of suitable organosilicon compounds used herein for silicon carbide based material deposition preferably include the structure: 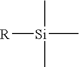
wherein R is an organic functional group, such as alkyl, alkenyl, cyclical, for example, cyclohexyl, and aryl groups, in addition to functional derivatives thereof. Hydrogen may be further bonded to the silicon compound. The organic compounds may have more than one R group attached to the silicon atom, and the invention contemplates the use of organosilicon compounds with or without Si—H bonds. Methylsilanes and phenylsilanes are preferred organosilicon compounds for silicon carbide based material deposition.

Aliphatic organosilicon compounds have linear or branched structures comprising one or more silicon atoms and one or more carbon atoms. Commercially available aliphatic organosilicon compounds include alkylsilanes. Cyclic organosilicon compounds typically have a ring comprising three or more silicon atoms. Fluorinated derivatives of the organosilicon compounds described herein may also be used to deposit the silicon carbide based materials and silicon oxycarbide material described herein.

Examples of suitable organosilicon compounds include, for example, one or more of the following compounds:

| | |
|---|---|
| Methylsilane, | CH₃—SiH₃ |
| Dimethylsilane, | (CH₃)₂—SiH₂ |
| Trimethylsilane (TMS), | (CH₃)₃—SiH |
| Tetramethylsilane, | (CH₃)₄—Si |
| Ethylsilane, | CH₃—CH₂—SiH₃ |
| Disilanomethane, | SiH₃—CH₂—SiH₃ |
| Bis(methylsilano)methane, | CH₃—SiH₂—CH₂—SiH₂—CH₃ |
| 1,2-disilanoethane, | SiH₃—CH₂—CH₂—SiH₃ |
| 1,2-bis(methylsilano)ethane, | CH₃—SiH₂—CH₂—CH₂—SiH₂—CH₃ |
| 2,2-disilanopropane, | SiH₃—C(CH₃)₂—SiH₃ |
| 1,3,5-trisilano- | —(—SiH₂—CH₂—)₃— (cyclic) |
| 2,4,6-trimethylene, | |
| Diethylsilane | (C₂H₅)₂SiH₂ |
| Diethylmethylsilane | (C₂H₅)₂SiH(CH₃) |
| Propylsilane | C₃H₇SiH₃ |
| Vinylmethylsilane | (CH₂═CH)(CH₃)SiH₂ |
| Divinyldimethylsilane | (CH₂═CH)₂(CH₃)₂Si |
| (DVDMS) | |
| 1,1,2,2-tetramethyldisilane | HSi(CH₃)₂—Si(CH₃)₂H |
| Hexamethyldisilane | (CH₃)₃Si—Si(CH₃)₃ |
| 1,1,2,2,3,3- | H(CH₃)₂Si—Si(CH₃)₂—SiH(CH₃)₂ |
| hexamethyltrisilane | |
| 1,1,2,3,3- | H(CH₃)₂Si—SiH(CH₃)—SiH(CH₃)₂ |
| pentamethyltrisilane | |
| Dimethyldisilanoethane | CH₃—SiH₂—(CH₂)₂—SiH₂—CH₃ |
| Dimethyldisilanopropane | CH₃—SiH₂—(CH₂)₃—SiH₂—CH₃ |
| Tetramethyldisilanoethane | (CH)₂—SiH—(CH₂)₂—SiH—(CH)₂ |
| Tetramethyldisilanopropane | (CH₃)₂—SiH—(CH₂)₃—SiH—(CH₃)₂ |

Phenyl containing organosilicon compounds, such as phenylsilanes may also be used for depositing the silicon carbide based materials and generally include the structure: 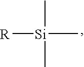
wherein R is a phenyl group. The compound may further have at least one silicon-hydrogen bond and may further have one or more organic functional groups, such as alkyl groups, cyclical groups, vinyl groups, or combinations thereof. For example, suitable phenyl containing organosilicon compounds generally include the formula SiHₐ(CH₃)_{b}(C₆H₅)_{c}, wherein a is 0 to 3, b is 0 to 3, and c is 1 to 4, and a+b+c is equal to 4. Examples of suitable compounds derived from this formula include diphenylsilane (DPS), dimethylphenylsilane (DMPS), diphenylmethylsilane, phenylmethylsilane, and combinations thereof. Preferably used are phenyl containing organosilicon compounds with b is 1 to 3 and c is 1 to 3. The most preferred phenyl organosilicon compounds for deposition as barrier layer materials include organosilicon compounds having the formula SiHₐ(CH₃)_{b}(C₆H₅)_{c}, wherein a is 1 or 2, b is 1 or 2, and c is 1 or 2. Examples of preferred phenyl compounds include dimethylphenylsilane and diphenylmethylsilane.

In one embodiment of the deposition process for silicon carbide described herein, the organosilicon compounds include alkyl, aryl, and/or cyclical organosilicon compounds having carbon to silicon atom ratios (C:Si) of 5:1 or greater, such as 8:1 or 9:1. Examples of alkyl functional groups having higher carbon alkyl groups, such as ethyl and iso-propyl functional groups, for example, dimethylisopropylsilane (5:1), diethylmethylsilane (5:1), tetraethylsilane (8:1), dibutylsilanes (8:1), tripropylsilanes (9:1), may be used. Examples of cyclical organosilicons, such as cyclopentylsilane (5:1) and cyclohexylsilane (6:1), including cyclical compounds having alkyl groups, such as ethylcyclohexylsilane (8:1) and propylcyclohexylsilanes (9:1) may also be used for the deposition of silicon carbon layers. Aryl compounds, for example, phenylsilanes (6:1) or dimethylphenylsilane (8:1), may also be used in depositing the silicon carbide layers described herein.

The processing gas may further include hydrogen gas, an inert gas, or a combination thereof. Suitable inert gases include a noble gas selected from the group of argon, helium, neon, xenon, or krypton, and combinations thereof, and nitrogen gas (N₂). The hydrogen gas is generally added at a molar ratio of organosilicon compound to hydrogen gas of between about 1:1 and about 10:1, such as between about 1:1 and about 6:1. Preferred deposition processes for oxygen-free organosilicon compounds and hydrogen gas have a molar ratio of oxygen-free organosilicon compound to hydrogen gas of between about 1:1 and about 1.5:1. Generally, the flow rate of the inert gas, hydrogen gas, or combinations thereof, are introduced into the processing chamber respectively, at flow rates between about 50 sccm and about 20,000 sccm.

An example of a phosphorus doped phenyl containing silicon carbide deposition process includes supplying dimethylphenylsilane, to a plasma processing chamber at a flow rate between about 10 milligrams/minute (mgm) and about 1500 mgm, for example, about 750 mgm, supplying a phosphorus containing compound at a flow rate between about 10 sccm and about 2000 sccm, for example, about 400 sccm, supplying hydrogen gas at a flow rate between about 10 sccm and about 2000 sccm, for example, about 500 sccm, supplying an inert gas at a flow rate between about 10 sccm and about 10000 sccm, for example, about 1500 sccm, maintaining a substrate temperature between about 0° C. and about 500° C., for example, about 350° C., maintaining a chamber pressure below about 500 Torr, for example, about about 6 Torr, and an RF power of between about 0.03 watts/cm² and about 1500 watts/cm², for example, about 200 watts at a gas distributor positioned between about 300 mils and about 600 mils, for example, about 450 mils, form the substrate surface during the deposition process.

The RF power can be provided at a high frequency, such as between 13 MHz and 14 MHz. The RF power can be provided continuously or in short duration cycles wherein the power is on at the stated levels for cycles less than about 200 Hz and the on cycles total between about 10% and about 30% of the total duty cycle. The processing gas may be introduced into the chamber by a gas distributor, the gas distributor may be positioned between about 200 mils and about 700 mils from the substrate surface. Alternatively, the plasma may be generated by a dual-frequency RF power source. The power may be applied from a dual-frequency RF power source a first RF power with a frequency in a range of about 10 MHz and about 30 MHz at a power, for example, 13.56 MHz, at a power range of about 100 watts to about 1000 watts and at least a second RF power with a frequency in a range of between about 100 KHz and about 500 KHz, such as about 356 kHz as well as a power, for example, in a range of about 1 watt to about 200 watts.

Example processes for depositing a phenyl containing silicon carbide layer is disclosed in U.S. Pat. Ser. No. 6,759,327, issued on Jul. 6, 2004, and U.S. Pate. No. 6,790,788, issued on Sep. 14, 2004, which are incorporated by reference to the extent not inconsistent with the claims and disclosure described herein.

The phosphorus doped silicon carbide layer may also be doped with boron, nitrogen, or oxygen to improve layer properties. Doped silicon carbide generally includes less than about 15 atomic % or less of any dopant including oxygen, nitrogen, boron, or combinations thereof. Boron doping of the low k silicon carbide layer may be performed by introducing borane (BH₃), or borane derivatives thereof, such as diborane (B₂H₆), into the chamber during the deposition process. The doped silicon carbide layer may comprise between about 0.1 wt. % and about 4 wt. % of boron. The boron may be used with oxygen and/or phosphorus dopants to form boron and phosphorus doped silicon carbide (SiCBP) and oxygen, boron, and phosphorus doped silicon carbide (SiCOBP).

Nitrogen doping may be achieved by including a nitrogen-containing gas, for example, ammonia (NH₃), nitrogen (N₂), a gas mixture of hydrogen and nitrogen, or combinations thereof, in the processing gas, or the use of silicon and nitrogen containing compounds. Suitable silicon and nitrogen containing compounds include compounds having Si—N—Si bonding groups, such as silazane compounds, may be used in the processing gas for doping the deposited silicon carbide based material with nitrogen. Compounds having bonded nitrogen, such as in the silazane compounds, can improve the hardness of layers as well as reduce the current leakage of the layers. Examples of suitable silazane compounds include aliphatic compounds, such as hexamethyldisilazane and divinyltetramethyidisilizane, as well as cyclic compounds, such as hexamethylcyclotrisilazane. Example processes for nitrogen doping a silicon carbide based material is disclosed in U.S. Pat. Ser. No. 6,764,958, issued on Jan. 20, 2005, and U.S. Pat. Ser. No. 6,537,733, issued on Mar. 25, 2003, which are incorporated by reference to the extent not inconsistent with the claims and disclosure described herein.

Oxygen doping of silicon carbide based materials typically include less than about 15 atomic percent (atomic %) of oxygen, preferably having between about 3 atomic % and about 10 atomic % of oxygen. Oxygen doped silicon carbide based material may be deposited with compounds containing oxygen and carbon, such as oxygen containing gases and oxygen containing organosilicon compounds. The oxygen-containing gas and the oxygen-containing organosilicon compounds described herein are considered non-oxidizing gases as compared to oxygen or ozone.

Preferred oxygen-containing gases generally have the formula C_{X}H_{Y}O_{Z}, with x being between 0 and 2, Y being between 0 and 2, where X+Y is at least 1, and Z being between 1 and 3, wherein X+Y+Z is 3 or less. Thus, the oxygen-containing gas may include carbon dioxide, carbon monoxide, or combinations thereof; and may additionally include water. The oxygen-containing gas is typically an inorganic material.

Alternatively, oxygen-doped silicon carbide based materials may be deposited with oxygen-containing organosilicon compounds to modify or change desired layer properties by controlling the oxygen content of the deposited silicon carbide based material. Suitable oxygen-containing organosilicon compounds include oxygen-containing aliphatic organosilicon compounds, oxygen-containing cyclic organosilicon compounds, or combinations thereof. Oxygen-containing aliphatic organosilicon compounds have linear or branched structures comprising one or more silicon atoms and one or more carbon atoms, and the structure includes silicon-oxygen bonds.

Oxygen-containing cyclic organosilicon compounds typically have a ring comprising three or more silicon atoms and the ring may further comprise one or more oxygen atoms. Commercially available oxygen-containing cyclic organosilicon compounds include rings having alternating silicon and oxygen atoms with one or two alkyl groups bonded to each silicon atom. Preferred oxygen-containing organosilicon compounds are cyclic compounds.

One class of oxygen-containing organosilicon compounds include compounds having Si—O—Si bonding groups, such as organosiloxane compounds. Compounds with siloxane bonds provide silicon carbide based materials with bonded oxygen that can reduce the dielectric constant of the layer as well as reduce the current leakage of the layer.

Suitable oxygen-containing organosilicon compounds include, for example, one or more of the following compounds:

| | |
|---|---|
| Dimethyldimethoxysilane (DMDMOS), | (CH₃)₂—Si—(OCH₃)₂, |
| Diethoxymethylsilane (DEMS), | (CH₃)—SiH—(OCH₃)₂, |
| 1,3-dimethyldisiloxane, | CH₃—SiH₂—O—SiH₂—CH₃, |
| 1,1,3,3-tetramethyldisiloxane (TMDSO), | (CH₃)₂—SiH—O—SiH—(CH₃)₂, |
| Hexamethyldisiloxane (HMDS), | (CH₃)₃—Si—O—Si—(CH₃)₃, |
| Hexamethoxydisiloxane (HMDSO), | (CH₃O)₃—Si—O—Si—(OCH₃)₃, |
| 1,3-bis(silanomethylene)disiloxane, | (SiH₃—CH₂—SiH₂—)₂—O, |
| Bis(1-methyldisiloxanyl)methane, | (CH₃—SiH₂—O—SiH₂—)₂—CH₂, |
| 2,2-bis(1-methyldisiloxanyl)propane, | (CH₃—SiH₂—O—SiH₂—)₂—C(CH₃),₂ |
| 1,3,5,7-tetramethylcyclotetrasiloxane (TMCTS), | —(—SiHCH₃—O—)₄— (cyclic), |
| Octamethylcyclotetrasiloxane (OMCTS), | —(—Si(CH₃)₂—O—)₄— (cyclic), |
| 1,3,5,7,9-pentamethylcyclopentasiloxane, | —(—SiHCH₃—O—)₅— (cyclic), |
| 1,3,5,7-tetrasilano-2,6-dioxy-4,8-dimethylene, | —(—SiH₂—CH₂—SiH₂—O—)₂—, |
| Hexamethylcyclotrisiloxane | —(—Si(CH₃)₂—O—)₃— (cyclic), |
| 1,3-dimethyldisiloxane, | CH₃—SiH₂—O—SiH₂—CH₃, |
| Hexamethylcyclotrisiloxane (HMDOS) | —(—Si(CH₃)₂—O—)₃— (cyclic), |

and fluorinated hydrocarbon derivatives thereof. The above lists are illustrative and should not be construed or interpreted as limiting the scope of the invention.

When oxygen-containing organosilicon compounds and oxygen-free organosilicon compounds are used in the same processing gas, a molar ratio of oxygen-free organosilicon compounds to oxygen-containing organosilicon compounds between about 4:1 and about 1:1 is generally used.

An phosphorus and oxygen-doped silicon carbide layer may be deposited in one embodiment by supplying organosilicon compounds, such as trimethylsilane, to a plasma processing chamber at a flow rate between about 10 milligrams/minute (mgm) and about 1500 mgm, or alternatively, between about 10 sccm and about 1500 sccm, for example about 160 mgm or sccm, supplying a phosphorus containing compound at a flow rate between about 10 sccm and about 2000 sccm, for example, about 400 sccm, supplying an oxidizing gas at a flow rate between about 10 sccm and about 2000 sccm, for example, about 700 sccm, supplying a noble gas at a flow rate between about 1 sccm and about 10000 sccm, for example, about 400 sccm, maintaining a substrate temperature between about 0° C. and about 500° C., for example, about 350° C., maintaining a chamber pressure below about 500 Torr, for example, about 2.5 Torr, at about and an RF power of between about 0.03 watts/cm² and about 1500 watts/cm², for example about 200 Watts with a gas distributor may be positioned between about 200 mils and about 700 mils, for example about 320 mils, from the substrate surface.

The RF power can be provided at a high frequency such as between 13 MHz and 14 MHz or a mixed frequency of the high frequency and the low frequency. For example, a high frequency of about 13.56 MHz may be used as well as a mixed frequency of high frequency of about 13.56 MHz and low frequency of about 356 KHz. The RF power can be provided continuously or in short duration cycles wherein the power is on at the stated levels for cycles less than about 200 Hz and the on cycles total between about 10% and about 30% of the total duty cycle. Additionally, a low frequency RF power may be applied during the deposition process to have a mixed frequency RF power application. For example, an application of less than about 300 watts, such as less than about 100 watts at between about 100 KHz and about 1 MHz, such as 356 KHz may be used to modify film properties, such as increase the compressive stress of a SiC film to reduce copper stress migration.

An example process for depositing an oxygen doped silicon carbide based material is disclosed in U.S. patent application Ser. No. 10/196,498, filed on Jul. 15, 2002, which is incorporated by reference to the extent not inconsistent with the claims and disclosure described herein.

Additional materials, such as organic compounds, may also be present during the deposition process to modify or change desired layer properties. For example, organic compounds, such as aliphatic hydrocarbon compounds may also be used in the processing gas to increase the carbon content of the deposited phosphorus doped silicon carbide materials. Suitable aliphatic hydrocarbon compounds include compounds having between one and about 20 adjacent carbon atoms. The hydrocarbon compounds can include adjacent carbon atoms that are bonded by any combination of single, double, and triple bonds.

Suitable organic compounds may include alkenes and alkynes having two to about 20 carbon atoms, such as ethylene, propylene, acetylene, and butadiene. Further examples of suitable hydrocarbons include t-butylethylene, 1,1,3,3-tetramethylbutylbenzene, t-butylether, metyl-methacrylate (MMA), t-butylfurfurylether, and combinations thereof. Organic compounds containing functional groups including oxygen and/or nitrogen containing functional groups may also be used. For example, alcohols, including ethanol, methanol, propanol, and iso-propanol, may be used for depositing the phosphorus doped silicon carbide material.

In an alternative embodiment of the deposition process for low k dielectric materials, the processing gas described herein may further include one or more meta-stable organic compounds. Meta-stable compounds are described herein as compounds having unstable functional groups that dissociate under applied processing conditions, such as by temperature applied during an annealing process. The meta-stable organic compounds form unstable components within the layer network. The unstable components may be removed from the deposited material using a post anneal treatment. The removal of the unstable component during the post anneal treatment forms a void within the network and reduces the dielectric constant of the deposited material. The meta-stable compound is also known as a “leaving group” because of the nature of the process whereby the meta-stable compound leaves the network to form one or more voids therein. For example, a t-butyl functional group dissociated from the molecule at about 200° C. to form ethylene (C₂H₄) by a beta hydrogenation mechanism and evolves from the substrate surface leaving behind a void in the deposited material.

The meta-stable organic compounds may include t-butylethylene, 1,1,3,3-tetramethylbutylbenzene, t-butylether, metyl-methacrylate (MMA), and t-butylfurfurylether. The meta-stable compounds may also be in the form of aliphatic compounds described herein. It is believed that the meta-stable organic compounds further reduce the dielectric constant of the deposited layer. Preferably, t-butylether is used as the meta-stable organic precursor in the processing gases.

A phosphorus doped silicon carbide barrier layer may generally be deposited by supplying an organosilicon compound to a plasma processing chamber at a flow rate between about 10 sccm and about 1500 sccm, supplying a phosphorus containing compound at a flow rate between about 10 sccm and about 2000 sccm, supplying an inert gas to the processing chamber at a flow rate between about 10 sccm and about 5000 sccm, optionally, supplying hydrogen gas at a flow rate between about 10 sccm and about 2000 sccm, optionally, for an oxygen doped silicon carbide material, supplying a compound comprising oxygen and carbon at a flow rate between about 10 sccm and about 2000 sccm, maintaining the chamber at a heater temperature between about 0° C. and about 500° C., maintaining a chamber pressure between about 100 millitorr and about 100 Torr, positioning a gas distributor between about 200 mils and about 700 mils from the substrate surface, and generating a plasma.

The plasma may be generated by applying a power density ranging between about 0.03 W/cm² and about 6.4 W/cm², which is a RF power level of between about 10 W and about 2000 W for a 200 mm substrate, for example, between about 100 W and about 400 W at a high frequency such as between 13 MHz and 14 MHz, for example, 13.56 MHz. The plasma may be generated by applying a power density ranging between about 0.01 W/cm² and about 2.8 W/cm², which is a RF power level of between about 10 W and about 2000 W for a 300 mm substrate, for example, between about 100 W and about 400 W at a high frequency such as between 13 MHz and 14 MHz, for example, 13.56 MHz. The RF power can be provided continuously or in short duration cycles wherein the power is on at the stated levels for cycles less than about 200 Hz and the on cycles total between about 10% and about 30% of the total duty cycle. Alternatively, all plasma generation may be performed remotely, with the generated radicals introduced into the processing chamber for plasma treatment of a deposited material or deposition of a material layer.

Alternatively, The power may be applied from a dual-frequency RF power source a first RF power with a frequency in a range of about 10 MHz and about 30 MHz at a power, for example, 13.56 MHz, at a power range of about 100 watts to about 1000 watts and at least a second RF power with a frequency in a range of between about 100 KHz and about 500 KHz, such as about 356 kHz as well as a power, for example, in a range of about 1 watt to about 200 watts. The above process parameters provide a deposition rate for the phosphorus doped silicon carbide layer in the range of about 500 Å/min to about 20,000 Å/min, such as a range between about 100 Å/min and about 3000 Å/min.

Post-Deposition Treatments:

The deposited phosphorus doped silicon carbide material may also be exposed to an anneal, a plasma treatment, an e-beam process, an ultraviolet treatment process, or a combination of treatments. The post-deposition treatments may be performed in situ (i.e., inside the same chamber or same processing system without breaking vacuum) with the deposition of the phosphorus doped silicon carbide material without breaking vacuum in a processing chamber or processing system.

Annealing the deposited material may comprise exposing the substrate at a temperature between about 100° C. and about 400° C. for between about 1 minute and about 60 minutes, preferably at about 30 minutes, to reduce the moisture content and increase the solidity and hardness of the dielectric material. Annealing is preferably performed after the deposition of a subsequent material, as described herein in the dual damascene description or layer that prevents shrinkage or deformation of the dielectric layer. The annealing process is typically performed using inert gases, such as argon and helium, but may also include hydrogen or other non-oxidizing gases. The above described annealing process is preferably used for low dielectric constant materials deposited from processing gases without meta-stable compounds. The anneal process is preferably performed prior to the subsequent deposition of additional materials. Preferably, an in-situ post treatment is performed.

The annealing process is preferably performed in one or more cycles using helium. The annealing process may be performed more than once, and variable constituents and concentrations of the annealing gases may be used in multiple processing steps or annealing steps. The anneal energy may be provided by the use of heat lamps, infrared (IR) radiation, such as IR heating lamps, or as part of a plasma anneal process. Alternatively, a RF power may be applied to the annealing gas between about 200 W and about 1,000 W, such as between about 200 W and about 800 W, at a frequency of about 13.56 MHz for a 200 mm substrate.

Alternatively, or additionally, the deposited phosphorus doped silicon carbide layer may be plasma treated to remove contaminants or otherwise clean the exposed surface of the phosphorus doped silicon carbide layer prior to subsequent deposition of materials thereon. The plasma treatment may be performed in the same chamber used to deposit the silicon and carbon containing material. The plasma treatment is also believed to improve layer stability by forming a protective layer of a higher density material than the untreated phosphorus doped silicon carbide material. The higher density phosphorus doped silicon carbide material is believed to be more resistive to chemical reactions, such as forming oxides when exposed to oxygen, than the untreated phosphorus doped silicon carbide material.

The plasma treatment generally includes providing an inert gas including helium, argon, neon, xenon, krypton, or combinations thereof, of which helium is preferred, and/or a reducing gas including hydrogen, ammonia, and combinations thereof, to a processing chamber. The inert gas and/or reducing gas is introduced into the processing chamber at a flow rate between about 500 sccm and about 3000 sccm, preferably between about 1000 sccm and about 2500 sccm of hydrogen, and generating a plasma in the processing chamber.

The plasma may be generated using a power density ranging between about 0.03 W/cm² and about 3.2 W/cm², which is a RF power level of between about 10 W and about 1000 W for a 200 mm substrate. Preferably, at a power level of about 100 watts for a phosphorus doped silicon carbide material on a 200 mm substrate. The RF power can be provided at a high frequency such as between 13 MHz and 14 MHz. The RF power can be provided continuously or in short duration cycles wherein the power is on at the stated levels for cycles less than about 200 Hz and the on cycles total between about 10% and about 30% of the total duty cycle. Alternatively, the RF power may also be provided at low frequencies, such as 356 kHz, for plasma treating the depositing phosphorus doped silicon carbide layer.

The processing chamber is preferably maintained at a chamber pressure of between about 1 Torr and about 12 Torr, for example about 3 Torr. The substrate is preferably maintained at a temperature between about 200° C. and about 450° C., preferably between about 290° C. and about 400° C., during the plasma treatment. A heater temperature of about the same temperature of the phosphorus doped silicon carbide deposition process, for example about 290° C., may be used during the plasma treatment. The plasma treatment may be performed between about 10 seconds and about 100 seconds, with a plasma treatment between about 40 seconds and about 60 seconds preferably used. The processing gas may be introduced into the chamber by a gas distributor. The gas distributor may be positioned between about 200 mils and about 1000 mils from the substrate surface. The gas distributor may be positioned between about 300 mils and about 600 mils during the plasma treatment.

The hydrogen containing plasma treatment is believed to further reduce the dielectric constant of the low k dielectric layer by about 0.1 or less. The plasma treatment is believed to clean contaminants from the exposed surface of the phosphorus doped silicon carbide material and may be used to stabilize the layer, such that it becomes less reactive with moisture and/or oxygen under atmospheric condition as well as the adhesion of layers formed thereover.

One example of a post deposition plasma treatment for a phosphorus doped silicon carbide layer includes positioning a gas distributor at about 280 mils from the substrate surface and introducing ammonia at a flow rate of 950 sccm into the processing chamber, maintaining the chamber at a heater temperature of about 350° C., maintaining a chamber pressure of about 3.7 Torr, and applying a RF power of about 300 watts at 13.56 MHz for about two seconds.

However, it should be noted that the respective parameters may be modified to perform the plasma processes in various chambers and for different substrate sizes, such as 200 mm substrates. An example of a plasma treatment for a silicon and carbon containing layer is further disclosed in U.S. Pat. Ser. No. 6,821,571, “Plasma Treatment to Enhance Adhesion and to Minimize Oxidation of Carbon-Containing Layers,” issued on Nov. 23, 2004, which is incorporated herein by reference to the extent not inconsistent with the disclosure and claimed aspects of the invention described herein.

Alternatively, the phosphorus doped silicon carbide layer may also be treated by depositing a silicon carbide cap layer or silicon oxide cap layer prior to depositing a resist material. The cap layer may be deposited at a thickness between about 100 Å and about 500Å. The use of a cap layer is more fully described in co-pending U.S. patent application No. 6,656,837, entitled “Method of Eliminating Resist Poisoning in Damascene Applications”, issued on Dec. 2, 2003, which is incorporated herein by reference to the extent not inconsistent with the claimed aspects and disclosure described herein.

In another aspect of the invention, the deposited phosphorus doped silicon carbide may be cured by an electronic beam (e-beam) technique. Silicon carbide based materials cured using an e-beam technique has shown an unexpected reduction in k value and an unexpected increase in hardness, not capable with conventional curing techniques. The e-beam treatment may be performed in situ within the same processing system, for example, transferred from one chamber to another without break in a vacuum. The following e-beam apparatus and process are illustrative, and should not be construed or interpreted as limiting the scope of the invention.

The temperature at which the electron beam apparatus operates ranges from about −200 degrees Celsius (° C.) to about 600° C., e.g., about 400° C. An e-beam treatment of a phosphorus doped silicon carbide layer may comprise the application or exposure to between about 1 micro coulomb per square centimeter (μC/cm²) and about 6,000 μC/cm², for example, between about 1 μC/cm² and about 400 μC/cm², and more preferably less than about 200 μC/cm², such as about 70 μC/cm², at energy ranges between about 0.5 kiloelectron volts (KeV) and about 30 KeV, for example between about 1 KeV and about 3 kiloelectron volts (KeV). The electron beams are generally generated at a pressure of about 1 mTorr to about 200 mTorr.

The gas ambient in the electron beam chamber may be an inert gas, including nitrogen, helium, argon, xenon, an oxidizing gas including oxygen, a reducing gas including hydrogen, a blend of hydrogen and nitrogen, ammonia, or any combination of these gases. The electron beam current ranges from about 1 mA to about 40 mA, and more preferably from about 5 mA to about 20 mA. The electron beam may cover an area from about 4 square inches to about 700 square inches. Although any e-beam device may be used, one exemplary device is the EBK chamber, available from Applied Materials, Inc., of Santa Clara, Calif.

An example of an e-beam process is as follows. A substrate having a 3000 Å thick layer is exposed to an e-beam at a chamber temperature about 400 degrees Celsius, an applied electron beam energy of about 3.5 KeV, and at an electron beam current of about 5 mA, with an exposure dose of the electron beam of about 500 mC/cm².

The deposited phosphorus doped silicon carbide material may then be cured by an ultraviolet curing technique. Silicon carbide based materials cured using the ultraviolet curing technique has shown improved barrier layer properties and reduced and minimal resist poisoning. The ultraviolet curing technique may be performed in situ within the same processing chamber or system, for example, transferred from one chamber to another without break in a vacuum. The following ultraviolet curing technique is illustrative, and should not be construed or interpreted as limiting the scope of the invention.

Exposure to an ultraviolet radiation source may be performed as follows. The substrate is introduced into a chamber, which may include the deposition chamber, and a deposited phosphorus doped silicon carbide layer is exposed to between about 0.01 milliWatts/cm² and about 1 waits/cm² of ultraviolet radiation, for example, between about 0.1 milliWatts/cm² and about 10 milliwatts/cm². The ultraviolet radiation may comprise a range of ultraviolet wavelengths, and include one or more simultaneous wavelengths. Suitable ultraviolet wavelengths include between about 1 nm and about 400 nm, and may further include optical wavelengths up to about 600 or 780 nm. The ultraviolet wavelengths between about 1 nm and about 400 nm, may provide a photon energy (electroVolts) between about 11.48 eV and about 3.5 eV. Preferred ultraviolet wavelengths include between about 100 nm and about 350 nm.

Further, the ultraviolet radiation application may occur at multiple wavelengths, a tunable wavelength emission and tunable power emission, or a modulation between a plurality of wavelengths as desired, and may be emitted from a single UV lamp or applied from an array of ultraviolet lamps. Examples of suitable UV lamps include a Xe filled Zeridex™ UV lamp, which emits ultraviolet radiation at a wavelength of about 172 nm or the Ushio Excimer UV lamp, or a Hg Arc Lamp, which emits ultraviolet radiation at wavelength of about 243 nm. The deposited phosphorus doped silicon carbide layer is exposed to the ultraviolet radiation for between about 10 seconds and about 600 seconds.

During processing, the temperature of the processing chamber may be maintained at between about 0° C. and about 450° C., e.g., between about 20° C. and about 400° C. degrees Celsius, for example about 25° C., and at a chamber pressure between vacuum, for example, less than about 1 mTorr up to about atmospheric pressure, i.e., 760 Torr, for example at about 100 Torr. The source of ultraviolet radiation may be between about 100 mils and about 600 mils from the substrate surface. Optionally, an ultraviolet curing processing gas may be introduced during the ultraviolet technique. Suitable curing gases include oxygen (O₂), nitrogen (N₂), hydrogen (H₂), helium (He), argon (Ar), water vapor (H₂O), carbon monoxide, carbon dioxide, hydrocarbon gases, fluorocarbon gases, and fluorinated hydrocarbon gases, or combinations thereof. The hydrocarbon compounds may have the formula C_{X}H_{Y}, C_{X}F_{Y}, C_{X}F_{Y}H_{Z}, or combinations thereof, with x an integer between 1 and 6, y is an integer between 4 and 14, and z is an integer between 1 and 3.

An example of an ultraviolet process is as follows. A substrate having a phosphorus doped silicon carbide layer is exposed to ultraviolet radiation at a chamber temperature about 25° C., an applied power of about 10 mW/cm² at a wavelength of about 172 nm for about 120 seconds. The ultraviolet treatment is further described in U.S. patent application Ser. No. 11/123,265, filed on May 5, 2005, which is incorporated herein to the extent not inconsistent with the description and claims aspects herein.

Deposition of a Barrier Layer for a Dual Damascene Structure

The phosphorus doped silicon carbide layer described herein may be used as a barrier layer, an etch stop, an anti-reflective coating, and/or a passivation layer in damascene formation, of which use as a barrier layer is preferred. Interlayer dielectric layers for use in low k damascene formations may have a phosphorus doped silicon carbide layer formed as described herein, include dielectric layers having silicon, oxygen, and carbon, and a dielectric constant of less than about 3. The adjacent dielectric layers for use with the barrier layer material described herein have a carbon content of about 1 atomic percent or greater, excluding hydrogen atoms, preferably between about 5 and about 30 atomic percent, excluding hydrogen atoms, and have oxygen concentrations of about 15 atomic % or greater. Phosphorus-doped silicon carbide layers have phosphorus concentrations of less than about 15 atomic % phosphorus.

The embodiments described herein for depositing phosphorus doped silicon carbide layers adjacent low k dielectric layers are provided to illustrate the invention and the particular embodiment shown should not be used to limit the scope of the invention.

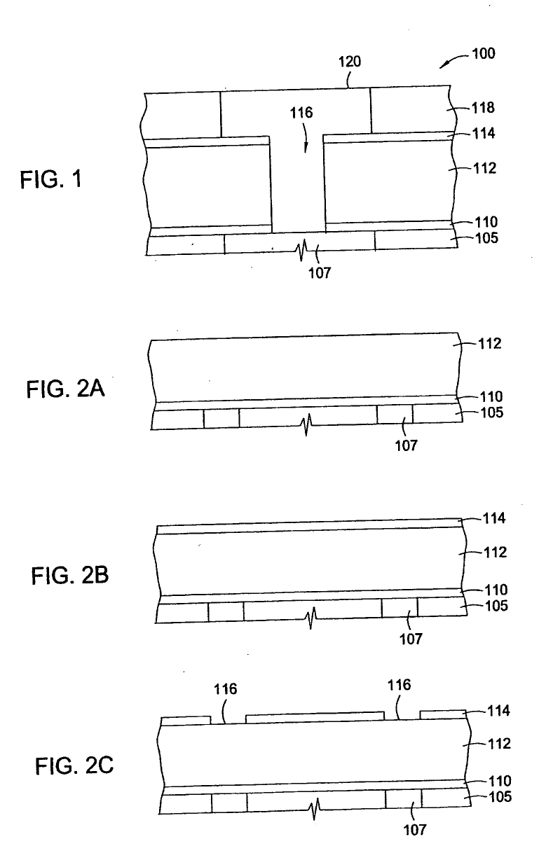

An example of a damascene structure that is formed using the bilayer described herein as a barrier layer is shown in FIG. 1. A damascene structure 100 is formed using a substrate 105 having conductive material features 107, such as copper features, formed therein is provided to a processing chamber. The conductive material features 107 include materials such as a metal or a non-metal conductive material, such as polysilicon or doped silicon. Metals include metal barrier materials, such as titanium, titanium nitride, tantalum, tantalum nitride, or combinations thereof, and fill materials, such as copper aluminum, or tungsten.

A barrier layer 110 is deposited on the substrate 105. The barrier layer 110 may comprise phosphorus doped silicon carbide as described herein and is generally deposited on the substrate surface to eliminate inter-level diffusion of materials including moisture and gases, such as oxygen. The barrier layer 110 of phosphorus doped silicon carbide as described herein provides an improved hermetic barrier to moisture and oxygen as compared to previously developed silicon carbide materials. While the barrier layer is described as phosphorus doped silicon carbide (SiCP), the barrier layer may further include oxygen and boron as described herein to form doped silicon carbide layers of SiCOP, SiCBP, or SiCOBP.

A first dielectric layer 112 is deposited on the barrier layer 110. An etch stop (or second barrier layer) 114 is then deposited on the first dielectric layer 112. The etch stop 114 may comprise a silicon carbide based material, such as the phosphorus doped silicon carbide material described herein. The etch stop is then pattern etched using conventional techniques to define the openings of the interconnects or contacts/vias.

A second dielectric layer 118, which may be same material as the first dielectric layer, is then deposited over the patterned etch stop 114. A resist is then deposited and patterned by conventional means known in the art to define the feature (contacts/via) definitions 116. A resist material may include an energy based resist material including deep ultraviolet (DUV) resist materials as well as e-beam resist materials. While not shown, an anti-reflective coating (ARC) layer and/or a cap layer, for example, of silicon oxide, silicon carbide, or phosphorus doped silicon carbide as described herein, may be deposited prior to depositing the resist layer.

A single etch process is then performed to define the contact/interconnect feature definition 116 down to the etch stop 114 and to etch the unprotected dielectric layer 112 and barrier layer 110 exposed by the patterned etch stop 114 to define the feature definitions (contacts/vias) 116. One or more conductive materials, such as copper are then deposited to fill the contacts/interconnect feature definitions 116. A passivation layer (not shown) of silicon carbide materials, such as the phosphorus doped silicon carbide material described herein, may be deposited on the second dielectric layer 118 and conductive materials. The passivation layer may perform as a barrier layer for another level of damascene structures formed as described herein.

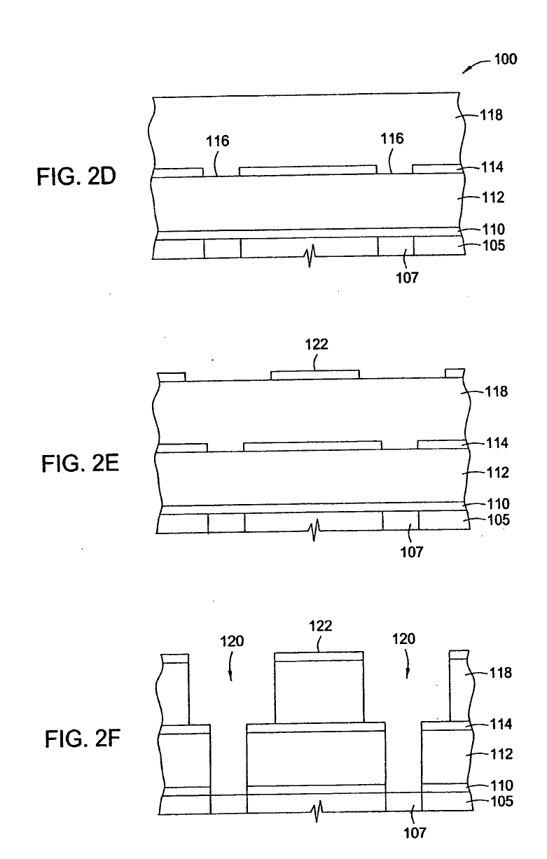

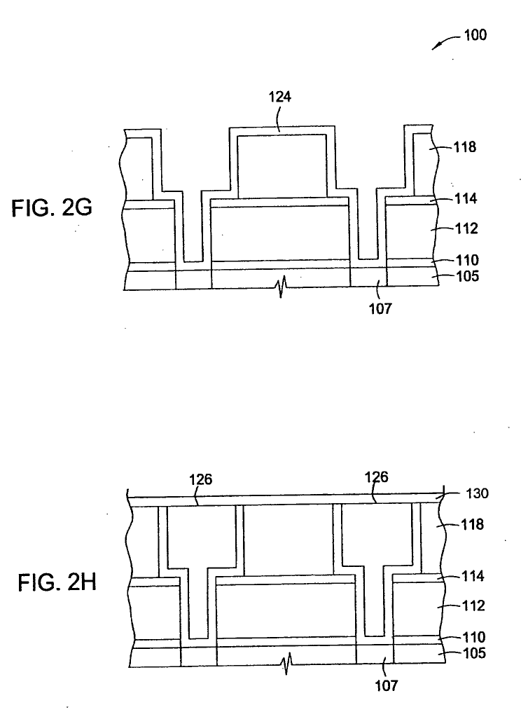

A preferred dual damascene structure fabricated in accordance with the invention including bilayers deposited by the processes described herein is sequentially depicted schematically in FIGS. 2A-2H, which are cross sectional views of a substrate having the steps of the invention formed thereon.

As shown in FIG. 2A, a barrier layer 110 is deposited on the substrate 105. The barrier layer 110 may be deposited to a thickness between about 50 Å and about 500 Å. The barrier layer 110 may comprise a phosphorus doped silicon carbide material and is deposited on the substrate surface from the processes described herein. The phosphorus doped silicon carbide material may be deposited by supplying an organosilicon compound to a plasma processing chamber at a flow rate between about 10 sccm and about 1500 sccm, supplying a phosphorus containing compound at a flow rate between about 10 sccm and about 2000 sccm, supplying an inert gas to the processing chamber at a flow rate between about 10 sccm and about 5000 sccm, optionally, supplying hydrogen gas at a flow rate between about 10 sccm and about 2000 sccm, optionally, supplying a compound comprising oxygen and carbon at a flow rate between about 10 sccm and about 2000 sccm, maintaining the chamber at a heater temperature between about 0° C. and about 500° C., maintaining a chamber pressure between about 100 milliTorr and about 100 Torr, positioning a gas distributor between about 200 mils and about 700 mils from the substrate surface, and generating a plasma by applying a RF power of between about 10 watts and about 2000 watts at 13.56 MHz to deposit a phosphorus doped silicon carbide layer. The deposited phosphorus doped silicon carbide layer may have a dielectric constant of about 2.5 to about 4.6.

The phosphorus doped silicon carbide barrier layer 110 may then be treated to one or more of the post-treatment processes described herein including anneal, plasma treatment, e-beam treatment, or an ultraviolet curing treatment as described herein. The pre-treatment, the phosphorus doped silicon carbide material, and any post-treatment process may be formed in the same processing chamber or same processing system without breaking vacuum. While not shown, a plasma pretreatment process of the substrate 105 may be performed prior to deposition of the phosphorus doped silicon carbide. Additionally, a capping layer (not shown), for example, of silicon oxide, may be deposited on the barrier layer 110.

Alternatively the barrier layer 110 may be a bilayer structure with the phosphorus doped silicon carbide material forming the upper or lower layer of the bilayer, with the remaining layer comprising a nitrogen doped silicon carbide, an oxygen doped silicon carbide, or a phenyl-containing silicon carbide layer. For example, the bottom layer may comprise a nitrogen and/or oxygen doped silicon carbide layer with the upper layer comprising the phosphorus doped silicon carbide material described herein.

The first dielectric layer 112 of interlayer dielectric material is deposited on the barrier layer 110. The first dielectric layer 112 may comprise silicon, oxygen, and carbon, and be deposited by oxidizing an organosilane or organosiloxane, such as trimethylsilane. Examples of methods and uses for the adjacent dielectric layers comprising silicon, oxygen, and carbon, having a dielectric constant of less than about 3 are more further described in U.S. Pat. No. 6,054,379, issued May 25, 2000, U.S. Pat. No. 6,287,990, issued Sep. 11, 2001, and U.S. Pat. No. 6,303,523, issued on Oct. 16, 2001, and in U.S. patent application Ser. No. 10/121,284, filed on Apr. 11, 2002, and U.S. patent application Ser. No. 10/302,393, filed on Nov. 22, 2002, all of which are incorporated by reference herein to the extent not inconsistent with the disclosure and claimed aspects described herein.

An example of a dielectric layer comprising silicon, oxygen, and carbon, having a dielectric constant of less than about 3 is Black Diamond™ dielectric materials commercially available from Applied Materials, Inc., of Santa Clara, Calif. Alternatively, the first dielectric layer may also comprise other low k dielectric material such as a low k polymer material including paralyne or a low k spin-on glass such as un-doped silicon glass (USG) or fluorine-doped silicon glass (FSG). The first dielectric layer 112 may be deposited to a thickness of about 5,000 Å to about 15,000 Å, depending on the size of the structure to be fabricated.

As shown in FIG. 2B, a low k etch stop 114 is then deposited on the first dielectric layer 112. The etch stop may be deposited to a thickness between about 200 Å and about 1000 Å. The etch stop 114 may be deposited from the same precursors and by the same process as the barrier layer 110, such as the phosphorus doped silicon carbide. The low k etch stop 114 may be treated as described herein for the barrier layer 110.

The low k etch stop may then be pattern etched to define feature definitions (contacts/via openings) 116 and to expose first dielectric layer 112 in the areas where the contacts/vias are to be formed as shown in FIG. 2C. Preferably, the low k etch stop 114 is pattern etched using conventional photolithography and etch processes using fluorine, carbon, and oxygen ions. While not shown, a nitrogen-free silicon carbide or silicon oxide cap layer between about 100 Å and about 500 Å thick may be deposited on the etch stop 114 prior to depositing further materials.

After the low k etch stop 114 has been etched to pattern the contacts/vias and the resist has been removed, a second dielectric layer 118 of silicon oxycarbide is deposited. The second dielectric layer may be deposited to a thickness between about 5,000 and about 15,000 Å as shown in FIG. 2D. The second dielectric layer 118 may be deposited as described for the first dielectric layer 112 as well as comprise the same materials used for the first dielectric layer 112. The first and second dielectric layer 118 may also be treated as described herein for barrier layer 110. All of the described layers 110, 112, 114, and 118 may be deposited in the same processing chamber or same processing system without breaking vacuum.

In an alternative embodiment, an anti-reflective coating layer, a cap layer, or a hardmask layer, may be deposited on the second dielectric layer 118 prior to depositing additional materials, such as resist materials for photolithographic process. Such a layer may be deposited between about 100 Å and about 500 Å thick. In one example, an ARC layer or hardmask of the phosphorus doped silicon carbide described herein may be disposed on the second dielectric layer 118, and then a photoresist may be deposited thereon. In a further embodiment, a nitrogen-free silicon carbide layer, such as the phosphorus doped silicon carbide layer described herein, or a silicon oxide cap layer may be deposited on second dielectric layer 118.

A resist material 122 is then deposited on the second dielectric layer 118 (or optional ARC layer or passivation layer as described with regard to FIG. 1) and patterned preferably using conventional photolithography processes to define the interconnect lines 120 as shown in FIG. 2E. The resist material 122 comprises a material conventionally known in the art, preferably a high activation energy resist, such as UV-5, commercially available from Shipley Company Inc., of Marlborough, Mass. The feature definitions (interconnects and contacts/vias) are then etched using reactive ion etching or other anisotropic etching techniques to define the metallization structure (i.e., the interconnect and contact/via) as shown in FIG. 2F. Any resist or other material used to pattern the etch stop 114 or the second dielectric layer 118 is removed using an oxygen strip or other suitable process.

The metallization structure is then formed with a conductive material such as aluminum, copper, tungsten or combinations thereof. Presently, the trend is to use copper to form the smaller features due to the low resistivity of copper (1.7 mΩ-cm compared to 3.1 mΩ-cm for aluminum). Preferably, as shown in FIG. 2G, a suitable barrier layer 124 for copper, such as tantalum or tantalum nitride, is first deposited conformally in the metallization pattern to prevent copper migration into the surrounding silicon and/or dielectric material. Thereafter, copper 126 is deposited using chemical vapor deposition, physical vapor deposition, electroplating, or combinations thereof to form the conductive structure. A seed layer of a conductive material, such as copper, may be deposited for bulk fill of the feature definition by the copper 126. Once the structure has been filled with copper or other metal, the surface is planarized using chemical mechanical polishing, as shown in FIG. 2H.

Following planarization of the barrier material 124 and conductive material 126, an optional passivation layer 130 may be deposited on the substrate. The passivation layer 130 may also perform as a barrier layer for another level of damascene structures that may be formed thereon. The passivation layer 130 may be deposited to a thickness between about 250 Å and about 1000 Å. The passivation layer 130 may comprise a phosphorus doped silicon carbide layer as deposited and treated herein.

While the foregoing is directed to preferred embodiments of the present invention, other and further embodiments of the invention may be devised without departing from the basic scope thereof, and the scope thereof is determined by the claims that follow.

1. A method for processing a substrate, comprising:
depositing a barrier layer on the substrate by
introducing into a processing chamber a processing gas comprising an oxygen-free organosilicon compound, a phosphorus containing gas, and hydrogen, wherein the oxygen-free organosilicon compound has the formula SiHₐ(CH₃)_{b}(C₆H₅)_{c}, and a is 0 to 3, b is 0 to 3, and c is 1 to 4; and
reacting the processing gas to deposit the barrier layer, wherein the barrier layer has a dielectric constant less than 5; and
depositing a dielectric layer adjacent the barrier layer, wherein the dielectric layer comprises silicon, oxygen, and carbon and has a dielectric constant of about 3 or less.

2. The method of claim 1, wherein the oxygen-free organosilicon compound has the formula SiHₐ(CH₃)_{b}(C₆H₅)_{c}, and a is 1 or 2, b is 1 or 2, and c is 1 or 2.

3. The method of claim 2, wherein the oxygen-free organosilicon compound comprises diphenylmethylsilane, dimethylphenylsilane, or combinations thereof.

4. The method of claim 1, wherein the barrier layer comprises between about 0.1 wt. % and about 15 wt. % of phosphorus.

5. The method of claim 4, wherein the barrier layer comprises between about 1 wt. % and about 4 wt. % of phosphorus.

6. The method of claim 1, wherein the phosphorus containing compound is selected from the group of phosphine (PH₃), triethylphosphate (TEPO), triethoxyphosphate (TEOP), trimethyl phosphine (TMP), triethyl phosphine (TEP), and combinations thereof.

7. The method of claim 1, wherein the processing gas further comprises an inert gas selected from the group of argon, helium, nitrogen, and combinations thereof.

8. The method of claim 1, wherein the processing gas further includes a boron-containing compound, an oxygen-containing compound, a nitrogen containing compound, or combinations thereof.

9. The method of claim 1, wherein the substrate is exposed to a plasma pre-treatment process, an e-beam curing technique, an ultra-violet curing technique, or combinations thereof, prior to depositing the barrier layer.

10. The method of claim 9, wherein the e-beam curing technique comprises applying between about 500 and about 6,000 micro coulombs per square centimeter (μc/cm²) at about 1 to 3 kiloelectron volts (KeV) to the barrier layer.

11. A method for processing a substrate, comprising:
depositing a barrier layer by a method comprising:
introducing to the processing chamber a processing gas comprising a compound comprising oxygen and carbon, an oxygen-free organosilicon compound, a phosphorus containing gas, and an inert gas; and
reacting the processing gas to deposit a barrier layer on the substrate, wherein the barrier layer comprises silicon, oxygen, and carbon and has an oxygen content of about 15 atomic percent or less and a dielectric constant of about 4 or less; and
depositing a dielectric layer adjacent the barrier layer, wherein the dielectric layer comprises silicon, oxygen, and carbon and has a dielectric constant of about 3 or less.

12. The method of claim 1 1, wherein the oxygen-free organosilicon compound comprises an organosilane compound selected from the group of methylsilane, dimethylsilane, trimethylsilane, ethylsilane, disilanomethane, bis(methylsilano)methane, 1,2-disilanoethane, 1,2-bis(methylsilano)ethane, 2,2-disilanopropane, 1,3,5-trisilano-2,4,6-trimethylene, and combinations thereof.

13. The method of claim 11, wherein the compound comprising oxygen and carbon has the formula C_{X}H_{Y}O_{Z}, with x being between 0 and 2, Y being between 0 and 2, and Z being between 1 and 3, wherein X+Y is at least 1 and X+Y+Z is 3 or less.

14. The method of claim 13, wherein the compound comprising oxygen and carbon is selected from the group of carbon monoxide, carbon dioxide, and combinations thereof.

15. The method of claim 11, wherein the inert gas is selected from the group of argon, helium, neon, xenon, or krypton, and combinations thereof.

16. The method of claim 11, wherein the barrier layer comprises between about 0.1 wt. % and about 15 wt. % of phosphorus.

17. The method of claim 16, wherein the barrier layer comprises between about 1 wt. % and about 4 wt. % of phosphorus.

18. The method of claim 11, wherein the phosphorus containing compound is selected from the group of phosphine (PH₃), triethylphosphate (TEPO), triethoxyphosphate (TEOP), trimethyl phosphine (TMP), triethyl phosphine (TEP), and combinations thereof.

19. The method of claim 18, wherein the compound comprising oxygen and carbon is carbon dioxide, the oxygen-free organosilicon compound is trimethylsilane, the phosphorus containing compound is phosphine (PH₃), and the inert gas is helium.

20. The method of claim 11, wherein the barrier layer has an oxygen content between about 3 atomic % and about 10 atomic %.
